(19) United States
(12) Patent Application Publication
(10) Pub. No.: US 2023/0215840 A1
(43) Pub. Date: Jul. 6, 2023

(54) SEMICONDUCTOR DEVICE

(71) Applicant: ROHM CO., LTD., Kyoto-shi, Kyoto (JP)

(72) Inventor: Masatsugu YUTANI, Kyoto-shi, Kyoto (JP)

(73) Assignee: ROHM CO., LTD., Kyoto-shi, Kyoto (JP)

(21) Appl. No.: 18/008,451

(22) PCT Filed: Jun. 15, 2021
(86) PCT No.: PCT/JP2021/022724

§ 371 Date: Dec. 6, 2022

(30) Foreign Application Priority Data
Jul. 27, 2020 (JP) 2020-126710

(51) Int. Cl. H01L 25/065; H01L 23/495; H01L 23/00; H10B 80/00

(52) U.S. Cl. CPC H01L 25/0655; H01L 23/49575; H01L 24/48; H01L 24/73; H10B 80/00; H01L 2224/48247; H01L 2224/73265

(57) ABSTRACT

A semiconductor device includes a semiconductor chip having a device forming surface on which a device structure is formed, a first conductive layer formed on the device forming surface of the semiconductor chip, a second conductive layer formed on the first conductive layer, a first wire that is connected to the second conductive layer and that is made of a material composed mainly of copper, and a third conductive layer that is formed between the first conductive layer and the second conductive layer and that includes a material harder than copper.

### TECHNICAL FIELD

The present disclosure relates to a semiconductor device.

### BACKGROUND ART

Patent Literature 1 discloses a semiconductor device including an insulating substrate that has a first electrode and a second electrode, a semiconductor element joined onto the first electrode by means of a sintered metal layer, a joint portion composed of a sintered copper layer that is provided on the semiconductor element and a metal containing layer with which a surface of the sintered copper layer is covered, a metallic sintered layer provided on the second electrode, and a metal wire one end of which is joined to the joint portion and one other end of which is joined to the second electrode through the metallic sintered layer.

### CITATION LIST

### Patent Literature

Patent Literature 1: Japanese Patent Application Publication No. 2018-147967

### SUMMARY OF INVENTION

### Solution to Problem

A semiconductor device according to a preferred embodiment of the present disclosure includes a semiconductor chip having a device forming surface on which a device structure is formed, a first conductive layer formed on the device forming surface of the semiconductor chip, a second conductive layer formed on the first conductive layer, a first wire that is connected to the second conductive layer and that is made of a material composed mainly of copper, and a third conductive layer that is formed between the first conductive layer and the second conductive layer and that includes a material harder than copper.

### BRIEF DESCRIPTION OF DRAWINGS

FIG. 1 is a schematic plan view of a semiconductor device according to a first preferred embodiment of the present disclosure.

FIG. 2 is a partial enlarged view of the semiconductor device of FIG. 1.

FIG. 3 is a partial enlarged view of the semiconductor device of FIG. 1.

FIG. 4 is a view showing a cross section along line IV-IV of FIG. 2.

FIG. 5 is a view showing a cross section along line V-V of FIG. 3.

FIG. 6 is a view shown to describe a joined state of a first wire.

FIG. 7 is a view shown to describe a joined state of a second wire.

FIG. 8A and FIG. 8B are views each showing a part of a manufacturing process of the semiconductor device.

FIG. 9A and FIG. 9B are views showing steps subsequent to the steps of FIG. 8A and FIG. 8B, respectively.

FIG. 10A and FIG. 10B are views showing steps subsequent to the steps of FIG. 9A and FIG. 9B, respectively.

FIG. 11A and FIG. 11B are views showing steps subsequent to the steps of FIG. 10A and FIG. 10B, respectively.

FIG. 12A and FIG. 12B are views showing steps subsequent to the steps of FIG. 11A and FIG. 11B, respectively.

FIG. 13A and FIG. 13B are views showing steps subsequent to the steps of FIG. 12A and FIG. 12B, respectively.

FIG. 14A and FIG. 14B are views showing steps subsequent to the steps of FIG. 13A and FIG. 13B, respectively.

FIG. 15A and FIG. 15B are views showing steps subsequent to the steps of FIG. 14A and FIG. 14B, respectively.

FIG. 16A and FIG. 16B are views showing steps subsequent to the steps of FIG. 15A and FIG. 15B, respectively.

FIG. 17A and FIG. 17B are views showing steps subsequent to the steps of FIG. 16A and FIG. 16B, respectively.

FIG. 18A and FIG. 18B are views showing steps subsequent to the steps of FIG. 17A and FIG. 17B, respectively.

FIG. 19 is a schematic cross-sectional view of a semiconductor device according to a second preferred embodiment of the present disclosure.

### DESCRIPTION OF EMBODIMENTS

### Preferred Embodiments of Present Disclosure

First, preferred embodiments of the present disclosure will be described in an itemized manner.

A semiconductor device according to one preferred embodiment of the present disclosure includes a semiconductor chip having a device forming surface on which a device structure is formed, a first conductive layer formed on the device forming surface of the semiconductor chip, a second conductive layer formed on the first conductive layer, a first wire that is connected to the second conductive layer and that is made of a material composed mainly of copper, and a third conductive layer that is formed between the first conductive layer and the second conductive layer and that includes a material harder than copper.

According to this arrangement, a force applied when the first wire is joined to the second conductive layer is lessened by the third conductive layer. This makes it possible to lessen the load of stress to the device structure, hence making it possible to provide a semiconductor device having high reliability.

The semiconductor device according to one preferred embodiment of the present disclosure may include a fourth conductive layer that is formed between the semiconductor chip and the first conductive layer and that includes a material harder than copper.

According to this arrangement, it is possible to lessen stress (for example, film stress) applied to the semiconductor chip by forming the fourth conductive layer, the first conductive layer, the third conductive layer, and the second conductive layer in order from the semiconductor chip side. This makes it possible to relax a warp of the semiconductor chip, hence making it possible to provide a semiconductor device having high reliability.

In the semiconductor device according to one preferred embodiment of the present disclosure, the fourth conductive layer may include a same material as the third conductive layer.

In the semiconductor device according to one preferred embodiment of the present disclosure, a thickness of the third conductive layer may be equal to or less than a thickness of the fourth conductive layer.

According to this arrangement, the thickness of the third conductive layer, which is one of the third and fourth conductive layers and which is closer to the second conductive layer (joint portion of the first wire), is set to be at least equal to or to be relatively smaller than the thickness of the fourth conductive layer, hereby making it possible to easily break the third conductive layer by means of a shock caused when the first wire is joined. This makes it possible to disperse stress generated when the first wire is joined, hence making it possible to provide a semiconductor device having higher reliability.

In the semiconductor device according to one preferred embodiment of the present disclosure, the device structure may include a concave portion formed at the semiconductor chip and an electroconductive embedded body embedded in the concave portion, and the first conductive layer may cover the concave portion.

If a concave portion is formed in the device structure, there is a case in which the shape of this concave portion is taken over to the first and second conductive layers. Hence, there is a concern that a load by stress generated when the first wire is joined will become larger than when the concave portion is not taken over. The semiconductor device according to the present preferred embodiment is likewise effective for a structure in which a load by such stress easily becomes large, and, as a result, it is possible to provide a semiconductor device having high reliability.

In the semiconductor device according to one preferred embodiment of the present disclosure, the device structure may include a first conductivity type first region and a second conductivity type second region contiguous to the first region, each of the first region and the second region being exposed to the concave portion, and the embedded body may be electrically connected to the first region and to the second region.

The semiconductor device according to one preferred embodiment of the present disclosure may further include an insulating layer formed between the semiconductor chip and the first conductive layer, a concave portion that passes through the insulating layer and that reaches an intermediate position of the semiconductor chip in a thickness direction of the semiconductor chip, a fourth conductive layer that is conformal to an inner surface of the concave portion and an upper surface of the insulating layer and that includes a material harder than copper, and an electroconductive embedded body embedded in the concave portion with the fourth conductive layer between the embedded body and the concave portion.

If a concave portion is formed in the semiconductor chip, there is a case in which the shape of this concave portion is taken over to the first and second conductive layers. Hence, there is a concern that a load by stress generated when the first wire is joined will become larger than when the concave portion is not taken over, and cracks will be made in the insulating layer. The semiconductor device according to the present preferred embodiment is likewise effective for a structure in which a load by such stress easily becomes large, and, as a result, it is possible to provide a semiconductor device having high reliability.

Additionally, it is possible to lessen stress (for example, film stress) applied to the semiconductor chip by forming the fourth conductive layer, the first conductive layer, the third conductive layer, and the second conductive layer in order from the semiconductor chip side. This makes it possible to relax a warp of the semiconductor chip.

In the semiconductor device according to one preferred embodiment of the present disclosure, the concave portions may be arranged at a pitch of 1 μm or less.

A load by stress generated when the first wire is joined easily becomes large in a miniaturized structure in which the concave portions are arranged at a pitch of 1 μm or less, and yet such a problem can also be solved if the semiconductor device according to the present preferred embodiment is used.

The semiconductor device according to one preferred embodiment of the present disclosure may include a fifth conductive layer that is formed on the device forming surface of the semiconductor chip and that is separated from the first conductive layer, a sixth conductive layer formed on the fifth conductive layer, a second wire connected to the sixth conductive layer, and a seventh conductive layer that is formed between the fifth conductive layer and the sixth conductive layer and that includes a material harder than copper.

In the semiconductor device according to one preferred embodiment of the present disclosure, a diameter of the second wire may be equal to a diameter of the first wire.

According to this arrangement, the first wire and the second wire can be joined to the second conductive layer and the sixth conductive layer, respectively, by use of the same bonding device. As a result, it is possible to provide a semiconductor device that can be manufactured effectively and at low cost.

In the semiconductor device according to one preferred embodiment of the present disclosure, the second wire may include a wire made of a material composed mainly of copper.

In the semiconductor device according to one preferred embodiment of the present disclosure, the device structure may include a gate electrode and a first impurity region and a second impurity region that are formed at the semiconductor chip and that make an electric current passage between the first impurity region and the second impurity region through a channel formed by applying a voltage to the gate electrode, and the first wire may be electrically connected to the first impurity region via the second conductive layer and the first conductive layer and the second wire may be electrically connected to the gate electrode via the sixth conductive layer and the fifth conductive layer.

In the semiconductor device according to one preferred embodiment of the present disclosure, the third conductive layer may include at least one of Ti and W.

In the semiconductor device according to one preferred embodiment of the present disclosure, a thickness of the third conductive layer may be equal to or less than 700 Å.

In the semiconductor device according to one preferred embodiment of the present disclosure, the first conductive layer and the second conductive layer may be made of a same material.

In the semiconductor device according to one preferred embodiment of the present disclosure, the first conductive layer and the second conductive layer may include AlCu.

In the semiconductor device according to one preferred embodiment of the present disclosure, a thickness of the second conductive layer may be not less than 2 μm and not more than 4.5 μm.

In the semiconductor device according to one preferred embodiment of the present disclosure, the second conductive layer may have a first thickness in a joint portion between the second conductive layer and the first wire, and may have a second thickness larger than the first thickness around the joint portion.

### Detailed Description of Preferred Embodiments of Present Disclosure

Next, preferred embodiments of the present disclosure will be described in detail with reference to the accompanying drawings. It should be noted that, in the following detailed description, there are a plurality of components each of which has a component name to which an ordinal number is assigned, and yet this ordinal number does not necessarily coincide with an ordinal number of a component recited in the appended claims.

### First Preferred Embodiment

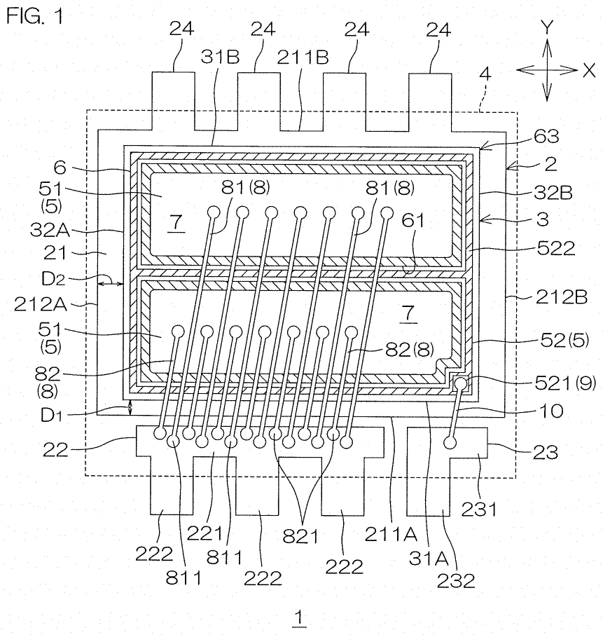

FIG. 1 is a schematic plan view of a semiconductor device 1 according to a first preferred embodiment of the present disclosure. For clarity, a package 4 is shown by an imaginary line (broken line), and other constituents are each shown by a solid line in FIG. 1.

The semiconductor device 1 includes a lead frame 2, a semiconductor element 3, and the package 4.

The lead frame 2 is formed in the shape of a metallic plate. The lead frame 2 is formed by applying a punching process, a cutout process, a bending process, etc., to a thin metal plate, such as a thin Cu plate, having a rectangular shape in a plan view. Therefore, the material of the lead frame 2 is composed mainly of Cu. However, the material of the lead frame 2 is not limited to this.

The lead frame 2 may include a die pad portion 21, a first lead portion 22, a second lead portion 23, and a third lead portion 24. The first lead portion 22, the second lead portion 23, and the third lead portion 24 may be referred to as a source lead portion, a gate lead portion, and a drain lead portion, respectively, in the present preferred embodiment. Additionally, the first lead portion 22, the second lead portion 23, and the third lead portion 24 each have a part that is exposed from the package 4 and that is connected to an external circuit of the semiconductor device 1, and hence may be referred to as a first terminal (source terminal), a second terminal (gate terminal), and a third terminal (drain terminal), respectively.

The die pad portion 21 has a quadrangular shape that has a pair of first sides 211A and 211B extending in a first direction X and a pair of second sides 212A and 212B extending in a direction intersecting the first direction X (in the present preferred embodiment, in a direction perpendicularly intersecting the first direction X) in a plan view.

The first lead portion 22, the second lead portion 23, and the third lead portion 24 are disposed around the die pad portion 21. In the present preferred embodiment, the first lead portion 22, the second lead portion 23, and the third lead portion 24 are disposed so as to adjoin the first and second sides 211A and 211B of the die pad portion 21. More concretely, the first lead portion 22 and the second lead portion 23 are disposed so as to adjoin the first side 211A, which is one of the first sides of the die pad portion 21, and the third lead portion 24 is disposed so as to adjoin the first side 211B, which is the other one of the first sides of the die pad. In other words, the first lead portion 22 and the second lead portion 23 are disposed on the side opposite to the third lead portion 24 with the die pad portion 21 between the first lead portion 22 or the second lead portion 23 and the third lead portion 24.

The first lead portion 22 is formed at a distance from the die pad portion 21. The first lead portion 22 may include a first pad portion 221 and a first lead 222. The first pad portion 221 is formed in the shape of a substantially rectangular shape that is long along the first side 211A of the die pad portion 21 in a plan view. The first lead 222 is formed integrally with the first pad portion 221, and extends from the first pad portion 221 in a direction intersecting a longitudinal direction of the first pad portion 221. The first lead 222 is formed as a plurality of first leads (in the present preferred embodiment, three first leads). The first leads 222 are arranged at a distance from each other along the longitudinal direction of the first pad portion 221 that is shared among the first leads 222, and are connected to the first pad portion 221 shared thereamong.

The second lead portion 23 is formed at a distance from both the die pad portion 21 and the first lead portion 22. The second lead portion 23 may include a second pad portion 231 and a second lead 232. The second pad portion 231 is formed in the shape of a substantially rectangular shape that is long along the first side 211A of the die pad portion 21. The second lead 232 is formed integrally with the second pad portion 231, and extends from the second pad portion 231 in a direction intersecting a longitudinal direction of the second pad portion 231. The second lead 232 is connected to the second pad portion 231 in a one-to-one correspondence. In the present preferred embodiment, the second lead portion 23 is disposed near one end portion of the first side 211A, which is one of the first sides of the die pad portion 21 (one corner portion of the die pad portion 21), and the first lead portion 22 extends along the first side 211A of the die pad portion 21 from the end portion of the first side 211A toward the other end portion of the first side 211A.

The third lead portion 24 is formed integrally with the die pad portion 21, unlike both the first lead portion 22 and the second lead portion 23. The third lead portion 24 extends from the first side 211B, which is the other one of the first sides of the die pad portion 21, in a direction intersecting the first side 211B. The third lead portion 24 is formed as a plurality of third lead portions (in the present preferred embodiment, four third lead portions). The third lead portions 24 are arranged at a distance from each other along the first side 211B of the die pad portion 21.

The semiconductor element 3 is disposed on the die pad portion 21 of the lead frame 2, and is supported by the die pad portion 21. The semiconductor element 3 has a quadrangular shape that has a pair of first sides 31A and 31B and a pair of second sides 32A and 32B and that is smaller than the die pad portion 21 in a plan view. In the present preferred embodiment, the semiconductor element 3 is disposed on the die pad portion 21 so that the first sides 31A and 31B become parallel to the first sides 211A and 211B of the die pad portion 21 and so that the second sides 32A and 32B become parallel to the second sides 212A and 212B of the die pad portion 21. A first distance D₁ between the first sides 211A, 211B of the die pad portion 21 and the first sides 31A, 31B of the semiconductor element 3 is shorter than a second distance D₂ between the second sides 212A, 212B of the die pad portion 21 and the second sides 32A, 32B of the semiconductor element 3. For example, the first distance D₁ may be equal to or less than ½ of the second distance D₂.

A conductive region 5 and an insulating region 6 are formed on one surface (in the present preferred embodiment, upper surface) of the semiconductor element 3. The conductive region 5 is partially covered with the insulating region 6. In FIG. 1, a part, which is covered with the insulating region 6, of the conductive region 5 is shown by a hatching region, and a part, which is exposed from the insulating region 6, of the conductive region 5 is shown by a white region. The conductive region 5 is a region to which a first wire 8 and a second wire 10, which are described later, are connected, and may be referred to as an electrode region.

The conductive region 5 is formed in substantially the whole area of the upper surface of the semiconductor element 3. The conductive region 5 may include a first conductive region 51 and a second conductive region 52. The first conductive region 51 and the second conductive region 52 are formed so as to be separated from each other.

The first conductive region 51 is formed as a plurality of first conductive regions. The first conductive regions 51 are formed so as to adjoin each other in a direction along the second sides 32A and 32B of the semiconductor element 3, and a gap region 61 is formed between the first conductive regions 51 adjoining each other. Additionally, a region around the first conductive region 51 may be an outer peripheral region 63. In other words, if the formation region of the first conductive region 51 is referred to as an active region, the outer peripheral region 63 may surround this active region. In the present preferred embodiment, each of the first conductive regions 51 is formed in a rectangular shape that is long along the first sides 31A and 31B of the semiconductor element 3 in a plan view. A part of the first conductive region 51 is exposed from the insulating region 6 as a first pad 7.

The first wire 8 is connected to the first pad 7. In the present preferred embodiment, the first wire 8 is a so-called Cu wire that is composed mainly of Cu. For example, a wire made of single component Cu (for example, the purity of Cu is equal to or more than 99.99%), a wire of a Cu alloy in which Cu is alloyed with other alloy components, a wire in which a single component Cu wire or a Cu alloy wire is covered with a conductive layer, etc., can be mentioned as the wire composed mainly of Cu. For example, Ag, Au, Al, Ni, Be, Fe, Ti, Pd, Zn, Sn, etc., can be mentioned as alloy components of the Cu alloy wire. Additionally, for example, Pd, etc., can be mentioned as covering components of the Cu wire covered with the conductive layer. The first wire 8 may use an Au wire or an Al wire as a modification. If the Au wire is used as a bonding wire, Au is high in cost and the cost is unstable depending on price fluctuations, and wire debonding will easily occur because of the fact that compound growth occurs between gold and aluminum in a high temperature environment. Additionally, if the Al wire is used as a bonding wire, recrystallization will easily occur in a high temperature environment because of the fact that aluminum has a comparatively low melting point. The use of the Cu wire as the first wire 8 makes it possible to provide a semiconductor device that has higher reliability than when the Au wire or the Al wire is used. For example, the first wire 8 may have a diameter of not less than φ₁ 18 μm and not more than φ₁ 50 μm when the Cu wire is used.

The first wire 8 connects the first pad 7 and the first pad portion 221 of the first lead portion 22 to each other. The first wire 8 may include a long wire 81 and a short wire 82 that is shorter than the long wire 81. The long wire 81 may be connected to the first pad 7 that is one of the pair of first pads 7 adjoining each other and that is placed on the side far from the first lead portion 22. On the other hand, the short wire 82 may be connected to the first pad 7 that is one of the pair of first pads 7 adjoining each other and that is placed on the side close to the first lead portion 22.

The long wire 81 and the short wire 82 are each provided as a plurality of wires, and may be alternately disposed along the longitudinal direction of the first pad portion 221. Additionally, a bonding portion 811 on the first pad portion 221 side of the long wire 81 and a bonding portion 821 on the first pad portion 221 side of the short wire 82 are disposed so as to be deflected to one side and to the other side, respectively, with respect to the longitudinal direction of the first pad portion 221. Hence, the bonding portion 811 of the long wire 81 and the bonding portion 821 of the short wire 82 are disposed so as to be deviated from each other, thus making it possible to prevent the bonding portions 811 and 821 from coming into contact with each other. As a result, it is possible to achieve a space-saving of the first lead portion 22.

The second conductive region 52 may integrally include a pad region 521 and a finger region 522. The pad region 521 is formed in the outer peripheral region 63, and is disposed at one corner portion of the semiconductor element 3 in the present preferred embodiment. The finger region 522 is formed in the outer peripheral region 63 from the pad region 521 along a peripheral edge portion of the semiconductor element 3. In the present preferred embodiment, the finger region 522 is formed along the first sides 31A, 31B and the second sides 32A, 32B of the semiconductor element 3 so as to surround the first conductive region 51. Additionally, the finger region 522 may be formed in the gap region 61 between the adjoining first conductive regions 51. Hence, each of the first conductive regions 51 is individually surrounded by the finger region 522.

The finger region 522 is covered with the insulating region 6, whereas a part of the pad region 521 is exposed from the insulating region 6 as a second pad 9.

The second wire 10 is connected to the second pad 9. The second wire 10 may be made of the same material as the first wire 8. In other words, the second wire 10 may be a so-called Cu wire composed mainly of Cu in the present preferred embodiment, and yet an Au wire or an Al wire may be used as a modification. Additionally, the second wire 10 may have the same diameter as the first wire 8. In other words, the second wire 10 may have a diameter of not less than φ₂ 18 μm and not more than φ₂ 50 μm if the second wire 10 is, for example, a Cu wire.

The second wire 10 connects the second pad 9 and the second pad portion 231 of the second lead portion 23 to each other. The second wire 10 may have a length shorter than the short wire 82 of the first wire 8.

The package 4 covers the semiconductor element 3, the first wire 8, the second wire 10, and a part of the lead frame 2, and may be referred to as a sealing resin. The package 4 is made of a material that has insulating properties. In the present preferred embodiment, the package 4 is made of, for example, a black epoxy resin.

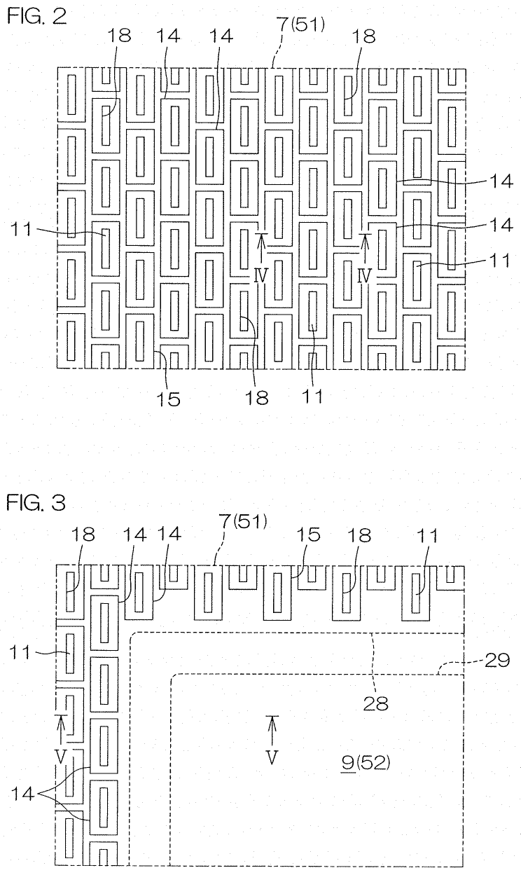

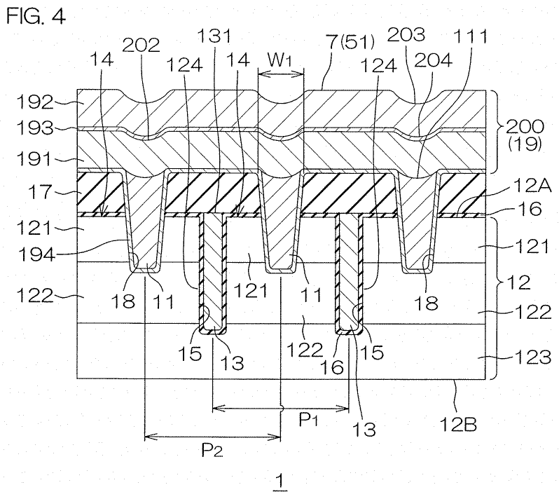

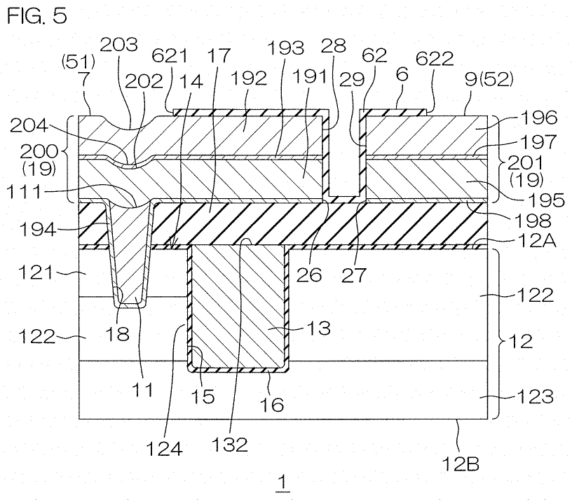

FIG. 2 is a partial enlarged view showing a planar structure below the first pad 7 of FIG. 1. FIG. 3 is a partial enlarged view showing a planar structure below the second pad 9 of FIG. 1. FIG. 4 is a view showing a cross section along line IV-IV of FIG. 2. FIG. 5 is a view showing a cross section along line V-V of FIG. 3. For clarity, the first conductive region 51 and the second conductive region 52 are each shown by an alternate long and two short dashed line or by a broken line in FIG. 3.

The semiconductor device 1 is composed of a semiconductor chip 12, a first impurity region 121 (source), a second impurity region 122 (body), a third impurity region 123 (drain), a gate trench 15 (first concave portion), a gate insulating film 16, a gate electrode 13 (first embedded body), an interlayer insulating film 17 (insulating layer), a source trench 18 (second concave portion), a contact plug 11 (second embedded body), a conductive layer 19, and an insulating film 62.

The semiconductor chip 12 forms the external shape of the semiconductor element 3, and is a structure in which, for example, a monocrystal semiconductor material is formed in a chip shape (rectangular parallelepiped shape). The semiconductor chip 12 is made of a semiconductor material, such as Si or SiC. The semiconductor chip 12 has a first principal surface 12A and a second principal surface 12B placed on the side opposite to the first principal surface 12A. The first principal surface 12A is a device surface on which a functional device is formed. The second principal surface 12B is a non-device surface on which a functional device is not formed. In the present preferred embodiment, the semiconductor chip 12 may include at least one of a semiconductor substrate and an epitaxial layer.

The first impurity region 121 is a p type impurity region selectively formed at a surface layer portion of the first principal surface 12A of the semiconductor chip 12 below the first conductive region 51 as shown in FIG. 4 and FIG. 5. The p type impurity concentration of the first impurity region 121 may be not less than 1×10¹⁸ cm⁻³ and not more than 1×10²⁰ cm⁻³. Additionally, the first impurity region 121 may be referred to as a p type source region in the present preferred embodiment.

The second impurity region 122 is an n type impurity region formed at the surface layer portion of the first principal surface 12A of the semiconductor chip 12. The second impurity region 122 is formed so as to be away from the first principal surface 12A toward the second principal surface 12B side and so as to become contiguous to the first impurity region 121. In other words, the second impurity region 122 faces the first principal surface 12A with the first impurity region 121 between the second impurity region 122 and the first principal surface 12A. The n type impurity concentration of the second impurity region 122 may be not less than 1×10¹⁵ cm⁻³ and not more than 1×10⁹ cm⁻³. Additionally, the second impurity region 122 may be referred to as an n type body region in the present preferred embodiment. Additionally, the second impurity region 122 is exposed from the first principal surface 12A of the semiconductor chip 12 below the second conductive region 52 as shown in FIG. 5.

The third impurity region 123 is a p type impurity region formed at a surface layer portion of the second principal surface 12B of the semiconductor chip 12. The third impurity region 123 is formed so as to be contiguous to the second impurity region 122, and is formed in the whole area of the surface layer portion of the second principal surface 12B, and is exposed from the second principal surface 12B. The p type impurity concentration of the third impurity region 123 is lower than the p type impurity concentration of the first impurity region 121, and may be, for example, not less than 1×10¹⁸ cm⁻³ and not more than 1×10² cm⁻³. The thickness of the third impurity region 123 may be not less than 1 μm and not more than 500 μm. Additionally, the third impurity region 123 may be referred to as a p type drift region or as a p type drain region in the present preferred embodiment.

The gate trench 15 (first concave portion) is a groove portion that passes through the first impurity region 121 and through the second impurity region 122 and that reaches the third impurity region 123. The gate trench 15 surrounds the first impurity region 121, the second impurity region 122, and the third impurity region 123 as shown in FIG. 2 and FIG. 3, thereby defining a transistor cell 14 including these regions 121, 122, and 123. In the present preferred embodiment, the transistor cell 14 is selectively formed in a region below the first conductive region 51 as shown in FIG. 2 and FIG. 3 while avoiding a region below the second conductive region 52. In other words, the transistor cell 14 is covered with the first conductive region 51, whereas the transistor cell 14 is not covered with the second conductive region 52.

The arrangement pattern of the transistor cells 14 is formed in a staggered manner in FIG. 2 and FIG. 3. The arrangement pattern of the transistor cells 14 may be formed in a matrix manner or in a stripe manner (not shown). Each of the transistor cells 14 is formed in a quadrangular shape in a plan view shown in FIG. 2 and FIG. 3, and is formed in a rectangular shape in the present preferred embodiment.

The gate trench 15 is formed between the transistor cells 14 arranged as above. The pitch P₁ between the adjoining gate trenches 15 is, for example, equal to or less than 1 μm as shown in FIG. 4. If the gate trenches 15 are ranged so as to surround each of the transistor cells 14 as shown in FIG. 2 and FIG. 3, the pitch P₁ between the gate trenches 15 may be, for example, a distance between the gate trenches 15 facing each other with the single transistor cell 14 between the gate trenches 15.

The gate insulating film 16 covers an inner surface of the gate trench 15 as shown in FIG. 4 and FIG. 5. Additionally, the gate insulating film 16 covers the first principal surface 12A of the semiconductor chip 12. The gate insulating film 16 is made of a material having insulating properties including, for example, SiO₂, SiN, etc.

The gate electrode 13 is embedded in the gate trench 15. The thus formed structure makes it possible to achieve miniaturization and low on-resistance as compared to a planar structure. Additionally, the gate insulating film 16 is insulated from the semiconductor chip 12 by means of the gate electrode 13, thereby making it possible to prevent the occurrence of a leakage current. The gate electrode 13 is a material having electrical conductivity including polysilicon, etc. Polysilicon is substantially equal in melting point to monocrystal silicon, and therefore the use of polysilicon as the gate electrode 13 makes it possible to eliminate restrictions on a process step depending on temperature in a process performed after the gate electrode 13 is formed.

The gate electrode 13 faces the second impurity region 122 with the gate insulating film 16 between the gate electrode 13 and the second impurity region 122. In the second impurity region 122, a side surface portion of the gate trench 15 facing the gate electrode 13 is a channel region 124. Carriers (in the present preferred embodiment, electrons) are induced in the channel region 124 by applying a voltage to the gate electrode 13, and an electric current is passed between the first impurity region 121 and the third impurity region 123. In other words, in the semiconductor device 1, a device structure is formed by the transistor cell 14 and the gate electrode 13.

The gate electrode 13 may have an upper surface 131 that is flush with the first principal surface 12A of the semiconductor chip 12 or that is hollowed toward the second principal surface 12B side below the first conductive region 51 as shown in FIG. 4. On the other hand, the gate electrode 13 may have an upper surface 132 that is flush with the first principal surface 12A of the semiconductor chip 12 or that is hollowed toward the second principal surface 12B side below the second conductive region 52 as shown in FIG. 5.

The interlayer insulating film 17 is formed on the first principal surface 12A of the semiconductor chip 12 so as to cover the gate insulating film 16 and the gate electrode 13. The interlayer insulating film 17 insulates the gate electrode 13 and a first conductive layer 191 from each other. Therefore, the gate electrode 13 is formed so as to be covered with the gate insulating film 16 and the interlayer insulating film 17. The interlayer insulating film 17 is a material having insulating properties including SiO₂, SiN, etc.

Referring to FIG. 2 and FIG. 3, the source trench 18 (second concave portion) is formed in each of the transistor cells 14. The source trench 18 is formed in each of the transistor cells 14 one by one in the present preferred embodiment, and yet a plurality of source trenches 18 may be formed in each of the transistor cells 14. The source trench 18 is formed in a rectangular shape in a plan view, which is long along the longitudinal direction of the transistor cell 14 having a rectangular shape in a plan view.

Referring to FIG. 4 and FIG. 5, the source trench 18 is a groove portion that reaches the second impurity region 122 through the interlayer insulating film 17, through the gate insulating film 16, and through the first impurity region 121. The source trench 18 is formed in a tapered manner in which an opening width W₁ becomes gradually smaller in proportion to extension in the depth direction of the source trench 18. Additionally, a pitch P₂ between the adjoining source trenches 18 is the same as the pitch P₁ between the gate trenches 15 as shown in FIG. 4, and is equal to or less than, for example, 1 μm.

The contact plug 11 is embedded in the source trench 18 with a first barrier layer 194 between the contact plug 11 and the source trench 18. The thus formed arrangement makes it possible to provide a semiconductor device 1 whose reliability has been improved by relaxing the electric field concentration of a bottom portion of the gate trench 15.

The first barrier layer 194 restrains the diffusion of a material forming the contact plug 11 into the interlayer insulating film 17. In the present preferred embodiment, the contact plug 11 may include W (tungsten), and the first barrier layer 194 may include a material that includes Ti (for example, a single layer structure of Ti or a layered structure of Ti and TiN). The thickness of the first barrier layer 194 is, for example, not less than 500 Å and not more than 700 Å.

The first barrier layer 194 has its one surface and its one other surface that are formed so as to follow an inner surface of the source trench 18 and an upper surface of the interlayer insulating film 17, and makes a direct electric current passage between the first barrier layer 194 and the first and second impurity regions 121, 122. Additionally, the first barrier layer 194 crosses a region above the gate trench 15, which is a boundary between the adjoining transistor cells 14, and continuously extends.

The contact plug 11 makes an electric current passage between the contact plug 11 and the first and second impurity regions 121, 122 through the first barrier layer 194. The contact plug 11 has an upper surface 111 that is concaved toward the first principal surface 12A side of the semiconductor chip 12 with respect to the upper surface of the interlayer insulating film 17.

Additionally, a second barrier layer 198 is formed on the interlayer insulating film 17. The second barrier layer 198 may include a material that includes Ti (for example, a single layer structure of Ti or a layered structure of Ti and TiN). The thickness of the second barrier layer 198 is equal to the thickness of the first barrier layer 194, and is, for example, not less than 500 Å and not more than 700 Å.

The second barrier layer 198 has its one surface and its one other surface that are formed so as to follow the upper surface of the interlayer insulating film 17, and makes a direct electric current passage between the second barrier layer 198 and the gate electrode 13 at a position not shown. Additionally, the second barrier layer 198 has an end edge 27 facing an end edge 26 of the first barrier layer 194 with an interval between the end edge 27 and the end edge 26 on the interlayer insulating film 17 as shown in FIG. 5.

The conductive layer 19 is formed on the interlayer insulating film 17. The conductive layer 19 has a plurality of portions separated from each other on the interlayer insulating film 17. In the present preferred embodiment, the conductive layer 19 may include a first conductive portion 200 and a second conductive portion 201 as the plurality of portions. The first conductive portion 200 and the second conductive portion 201 have upper surfaces formed as the aforementioned first conductive region 51 and the aforementioned second conductive region 52, respectively. Additionally, the first conductive portion 200 and the second conductive portion 201 may be referred to as a source electrode layer and a gate electrode layer or a source electrode film and a gate electrode film on the basis of their electrical to-be-connected objects, or may be referred to as a first electrode and a second electrode by use of ordinal numbers.

The first conductive portion 200 has a plurality of layers laminated in order from the interlayer insulating film 17 as shown in FIG. 4 and FIG. 5. In the present preferred embodiment, the first conductive portion 200 may include the first conductive layer 191, a second conductive layer 192, and a third conductive layer 193. The first conductive layer 191, the second conductive layer 192, and the third conductive layer 193 are formed in the whole area of the first conductive portion 200 in an in-plane direction perpendicular to a layered direction of the first conductive portion 200, and are each exposed to an end surface 28 of the first conductive portion 200. In other words, boundaries among the first, second, and third conductive layers 191, 192, and 193 are exposed to the end surface 28. Additionally, the end surface 28 may be flush with the end edge 26 of the first barrier layer 194.

The first conductive layer 191 is formed on the interlayer insulating film 17 so as to cover the contact plug 11. The first conductive layer 191 is contiguous to the upper surface 111 of the contact plug 11 on the source trench 18, and is contiguous to the first barrier layer 194 on the interlayer insulating film 17. Therefore, a part of the first barrier layer 194 is sandwiched between the interlayer insulating film 17 and the first conductive layer 191. The first conductive layer 191 makes an electric current passage between the first conductive layer 191 and the first and second impurity regions 121, 122 through the first barrier layer 194 and the contact plug 11. The first conductive layer 191 is made of, for example, a material including Al, and is made of AlCu in the present preferred embodiment. Additionally, the thickness of the first conductive layer 191 may be equal to or less than, for example, 2.5 μm.

The second conductive layer 192 is formed on the first conductive layer 191 with the third conductive layer 193 between the second conductive layer 192 and the first conductive layer 191. The second conductive layer 192 is a surface conductive layer that is an outermost surface of the first conductive portion 200, and is a layer to which the first wire 8 mentioned above is connected. Therefore, an upper surface of the second conductive layer 192 is exposed as the first pad 7. The second conductive layer 192 makes an electric current passage between the second conductive layer 192 and the first and second impurity regions 121, 122 through the first barrier layer 194, through the contact plug 11, through the third conductive layer 193, and through the first conductive layer 191. The second conductive layer 192 is made of the same material as the first conductive layer 191 (for example, material that includes Al), and is made of AlCu in the present preferred embodiment. Additionally, the thickness of the second conductive layer 192 is smaller than the thickness of the first conductive layer 191, and may be, for example, not less than 2 μm and not more than 4.5 μm.

The third conductive layer 193 is formed between the first conductive layer 191 and the second conductive layer 192, and is sandwiched between the first conductive layer 191 and the second conductive layer 192. The third conductive layer 193 is made of, for example, a material that is harder than Cu (copper) and that includes at least one of Ti and W, and, in the present preferred embodiment, the third conductive layer 193 has a layered structure (Ti/TiN) in which Ti and TiN are laminated in order from a boundary between the third conductive layer 193 and the first conductive layer 191. The thickness of the third conductive layer 193 is equal to or less than the thickness of the first barrier layer 194, and is equal to or less than, for example, 700 Å.

The upper surface 111 of the contact plug 11 is concaved toward the upper surface of the interlayer insulating film 17 as described above. Therefore, a concave portion 202 may be formed at a position, which faces the upper surface 111 in the layered direction of the first conductive portion 200, of the upper surface of the first conductive layer 191. Additionally, a concave portion 203 may be formed at a position, which faces the upper surface 111 in the layered direction of the first conductive portion 200, of the upper surface of the second conductive layer 192. Additionally, a concave portion 204 may be formed at a position, which faces the upper surface 111 in the layered direction of the first conductive portion 200, of the upper surface of the third conductive layer 193.

In other words, a part of an interface between the first conductive layer 191 and the third conductive layer 193 may selectively protrude toward the source trench 18. Additionally, a part of an interface between the third conductive layer 193 and the second conductive layer 192 may selectively protrude toward the source trench 18.

As thus described, the first conductive portion 200 has a structure in which the third conductive layer 193 is sandwiched between the first conductive layer 191 and the second conductive layer 192. Therefore, in the present preferred embodiment, the third conductive layer 193 may be referred to as a first intermediate layer, and the first conductive layer 191 may be referred to as a first lower conductive layer, and the second conductive layer 192 may be referred to as a second upper conductive layer. Additionally, the third conductive layer 193 relaxes stress when a Cu wire is connected to the second conductive layer 192 as described later, and therefore the third conductive layer 193 may be referred to as a first relaxing layer (buffer layer) or as a first stress relaxing layer.

The second conductive portion 201 has a plurality of layers laminated in order from the interlayer insulating film 17 as shown in FIG. 5. In the present preferred embodiment, the second conductive portion 201 may include a fourth conductive layer 195, a fifth conductive layer 196, and a sixth conductive layer 197. The fourth conductive layer 195, the fifth conductive layer 196, and the sixth conductive layer 197 are formed in the whole area of the second conductive portion 201 in an in-plane direction perpendicular to a layered direction of the second conductive portion 201, and are each exposed to an end surface 29 of the second conductive portion 201. In other words, boundaries among the fourth, fifth, and sixth conductive layers 195, 196, and 197 are exposed to the end surface 29. Additionally, the end surface 29 may be flush with the end edge 27 of the second barrier layer 198. Additionally, the end surface 29 of the second conductive portion 201 faces the end surface 28 of the first conductive portion 200 across a space.

The fourth conductive layer 195 is formed on the interlayer insulating film 17. The fourth conductive layer 195 is contiguous to the gate electrode 13 at a position (not shown), and is contiguous to the second barrier layer 198 on the interlayer insulating film 17. Therefore, a part of the second barrier layer 198 is sandwiched between the interlayer insulating film 17 and the fourth conductive layer 195. The fourth conductive layer 195 makes an electric current passage between the fourth conductive layer 195 and the gate electrode 13 through the second barrier layer 198. The fourth conductive layer 195 is made of, for example, a material including Al, and is made of AlCu in the present preferred embodiment. Additionally, the thickness of the fourth conductive layer 195 is equal to the thickness of the first conductive layer 191, and may be equal to or less than, for example, 2.5 μm.

The fifth conductive layer 196 is formed on the fourth conductive layer 195 with the sixth conductive layer 197 between the fifth conductive layer 196 and the fourth conductive layer 195. The fifth conductive layer 196 is a surface conductive layer that is an outermost surface of the second conductive portion 201, and is a layer to which the second wire 10 mentioned above is connected. Therefore, an upper surface of the fifth conductive layer 196 is exposed as the second pad 9. The fifth conductive layer 196 makes an electric current passage between the fifth conductive layer 196 and the gate electrode 13 through the second barrier layer 198, through the fourth conductive layer 195, and through the sixth conductive layer 197. The fifth conductive layer 196 is made of the same material as the fourth conductive layer 195 (for example, material that includes Al), and is made of AlCu in the present preferred embodiment. Additionally, the thickness of the fifth conductive layer 196 is smaller than the thickness of the fourth conductive layer 195, and may be, for example, not less than 2 μm and not more than 4.5 μm. Additionally, the thickness of the fifth conductive layer 196 may be equal to the thickness of the second conductive layer 192.

The sixth conductive layer 197 is formed between the fourth conductive layer 195 and the fifth conductive layer 196, and is sandwiched between the fourth conductive layer 195 and the fifth conductive layer 196. The sixth conductive layer 197 is made of, for example, a material that is harder than Cu (copper) and that includes at least one of Ti and W, and, in the present preferred embodiment, the sixth conductive layer 197 has a layered structure (Ti/TiN) in which Ti and TiN are laminated in order from a boundary between the sixth conductive layer 197 and the fourth conductive layer 195. The thickness of the sixth conductive layer 197 is equal to or less than the thickness of the second barrier layer 198, and is equal to or less than, for example, 700 Å. Additionally, the thickness of the sixth conductive layer 197 may be equal to the thickness of the third conductive layer 193.

As thus described, the second conductive portion 201 has a structure in which the sixth conductive layer 197 is sandwiched between the fourth conductive layer 195 and the fifth conductive layer 196. Therefore, in the present preferred embodiment, the sixth conductive layer 197 may be referred to as a second intermediate layer, and the fourth conductive layer 195 may be referred to as a second lower conductive layer, and the fifth conductive layer 196 may be referred to as a second upper conductive layer. Additionally, the sixth conductive layer 197 relaxes stress when a Cu wire is connected to the fifth conductive layer 196 as described later, and therefore the sixth conductive layer 197 may be referred to as a second relaxing layer (buffer layer) or as a second stress relaxing layer.

Additionally, the fourth conductive layer 195, the fifth conductive layer 196, and the sixth conductive layer 197 may have upper surfaces, respectively, that are flat and on which the concave portions 202 to 204 are not formed, unlike the first conductive layer 191, the second conductive layer 192, and the third conductive layer 193.

The insulating film 62 is formed on the interlayer insulating film 17 so as to cover the conductive layer 19. The end surface 28 of the first conductive portion 200, the end edge 26 of the first barrier layer 194, the upper surface of the interlayer insulating film 17, the end edge 27 of the second barrier layer 198, and the end surface 29 of the second conductive portion 201 are integrally covered in a boundary portion between the first conductive portion 200 and the second conductive portion 201. The insulating film 62 is made of a material having insulating properties that includes, for example, SiN, etc. The insulating film 62 is a film that protects an outermost surface of the semiconductor chip 12, and therefore may be referred to as, for example, a surface protection film or a surface insulating film. The insulating film 62 has an upper surface formed as the aforementioned insulating region 6. Additionally, a first opening 621 that exposes a part of the first conductive portion 200 as the first pad 7 and a second opening 622 that exposes a part of the second conductive portion 201 as the second pad 9 are formed in the insulating film 62. The first pad 7 may include the concave portion 203 of the second conductive layer 192.

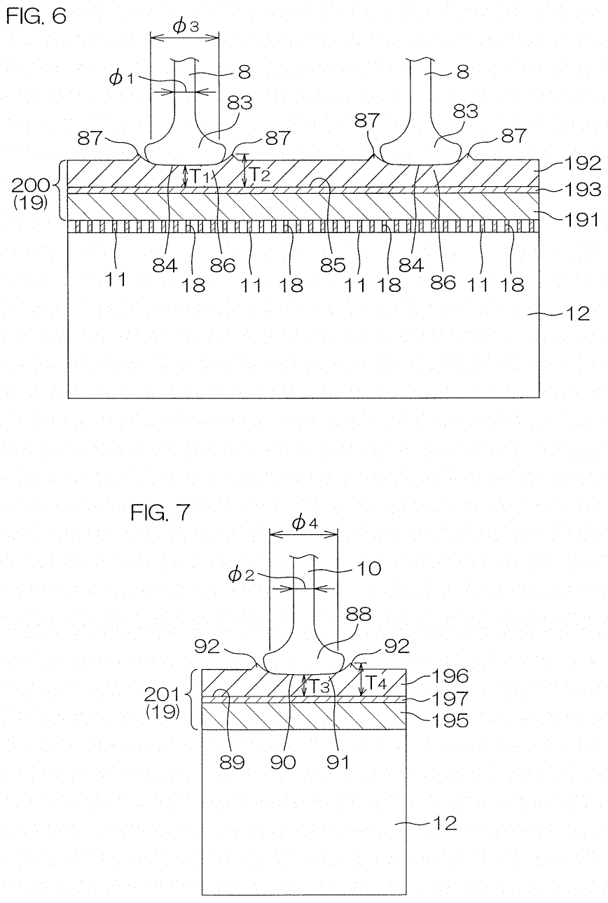

FIG. 6 is a view showing a joined state of the first wire 8 of the semiconductor device 1 according to the first preferred embodiment of the present disclosure. FIG. 7 is a view showing a joined state of the second wire 10 of the semiconductor device 1 according to the first preferred embodiment of the invention. For clarity, only some of the constituents shown in FIG. 4 and FIG. 5 that are necessary to describe joined states of the first and second wires 8 and 10 are shown in FIG. 6 and FIG. 7.

A joined state of the first wire 8 of the semiconductor device 1 according to the first preferred embodiment will be described with reference to FIG. 6.

The first wire 8 is joined to the second conductive layer 192. The first wire 8 has a joint portion 83 contiguous to the second conductive layer 192. The joint portion 83 is formed by so-called ball bonding. The joint portion 83 is joined to the second conductive layer 192 at a distance from a boundary 85 between the second conductive layer 192 and the third conductive layer 193 in the layered direction of the first conductive portion 200. Therefore, a part of the second conductive layer 192 is interposed between a joint surface 84 of the joint portion 83 and the boundary 85, and the joint portion 83 does not come into direct contact with the third conductive layer 193.

Additionally, the joint surface 84 of the first wire 8 has a diameter φ₃ larger than a diameter φ₁ of the first wire 8. The diameter φ₃ of the joint surface 84 is, for example, not less than 150 μm and not more than 160 μm. Hence, the joint surface 84 of the first wire 8 may cover the contact plugs 11 (source trenches 18) the number of which is not less than 100 and not more than 200 in the layered direction of the first conductive portion 200. For clarity, the source trench 18 is shown at a great ratio with respect to the first wire 8 in FIG. 6.

Additionally, the second conductive layer 192 has its region that is contiguous to the joint surface 84 of the first wire 8 and that is selectively concaved, and the periphery of the region is selectively raised. In the present preferred embodiment, the second conductive layer 192 may include a joint portion 86 sandwiched between the joint surface 84 of the first wire 8 and the third conductive layer 193 and a raised portion 87 formed around the joint portion 86. The thickness T₁ of the joint portion 86 (distance from the boundary 85 to the joint surface 84) is smaller than the thickness T₂ of the raised portion 87 (distance from the boundary 85 to a top portion of the raised portion 87).

Next, a joined state of the second wire 10 of the semiconductor device 1 according to the first preferred embodiment will be described with reference to FIG. 7.

The second wire 10 is joined to the fifth conductive layer 196. The second wire 10 has a joint portion 88 contiguous to the fifth conductive layer 196. The joint portion 88 is formed by so-called ball bonding. The joint portion 88 is joined to the fifth conductive layer 196 at a distance from a boundary 89 between the fifth conductive layer 196 and the sixth conductive layer 197 in the layered direction of the second conductive portion 201. Therefore, a part of the fifth conductive layer 196 is interposed between a joint surface 90 of the joint portion 88 and the boundary 89, and the joint portion 88 does not come into direct contact with the sixth conductive layer 197.

Additionally, the joint surface 90 of the second wire 10 has a diameter φ₄ larger than a diameter φ₂ of the second wire 10. The diameter 94 of the joint surface 90 is, for example, not less than 150 μm and not more than 160 μm.

Additionally, the fifth conductive layer 196 has its region that is contiguous to the joint surface 90 of the second wire 10 and that is selectively concaved, and the periphery of the region is selectively raised. In the present preferred embodiment, the fifth conductive layer 196 may include a joint portion 91 sandwiched between the joint surface 90 of the second wire 10 and the sixth conductive layer 197 and a raised portion 92 formed around the joint portion 91. The thickness T₃ of the joint portion 91 (distance from the boundary 89 to the joint surface 90) is smaller than the thickness T₄ of the raised portion 92 (distance from the boundary 89 to a top portion of the raised portion 92).

As described above, in the semiconductor device 1, a Cu wire is used as the first wire 8. For example, if the Au wire is used as the bonding wire, Au is high in cost and the cost is unstable depending on price fluctuations, and wire debonding will easily occur because of the fact that compound growth occurs between gold and aluminum in a high temperature environment. Additionally, if an Al wire is used as the bonding wire, recrystallization will easily occur in a high temperature environment because of the fact that aluminum has a comparatively low melting point. The use of a Cu wire as the first wire makes it possible to provide a semiconductor device that has higher reliability than when an Au wire or an Al wire is used.

On the other hand, the first wire 8 is joined to the second conductive layer 192 by means of solid phase bonding, such as solid phase diffusion bonding, friction pressure welding, or ultrasonic joining. Therefore, stress is applied to a device structure including the transistor cell 14 because of heat generated when the first wire 8 (Cu wire) is joined to the second conductive layer 192 by means of solid phase junction, because of a load applied in the layered direction of the conductive layer 19, and because of a burden generated by vibrations applied in a direction perpendicular to the layered direction of the conductive layer 19.

In this respect, in the present preferred embodiment, the third conductive layer 193 is formed between the first conductive layer 191 and the second conductive layer 192 below the first conductive region 51. Hence, a force applied when the first wire 8 (Cu wire) is joined to the second conductive layer 192 is lessened by the third conductive layer 193. This makes it possible to lessen the load of stress to the device structure including the transistor cell 14, hence making it possible to provide a semiconductor device 1 having high reliability.

Moreover, if a concave portion, such as the source trench 18, is formed in the first principal surface 12A of the semiconductor chip 12 as in the present preferred embodiment, there is a case in which the shape of this concave portion is taken over to the first and second conductive layers 191 and 192. For example, there is a case in which the upper surface 111, which has been concaved, is formed at the contact plug 11 formed by embedding a conductive material in the source trench 18 as shown in FIG. 4 and FIG. 5. Additionally, there is a case in which the shape of this upper surface 111 is taken over to the first conductive layer 191 as the concave portion 202 and is taken over to the second conductive layer 192 as the concave portion 203. If the concave portions 202 and 203 are formed in this way, there is a concern that a load by stress generated when the Cu wire is joined will become larger than when these concave portions are not formed, and cracks will be made in, for example, the interlayer insulating film 17, etc., directly under the conductive layer 19. The semiconductor device 1 according to the present preferred embodiment is also effective for a structure in which a load by such stress easily becomes large, and, as a result, it is possible to provide a semiconductor device 1 having high reliability.

Additionally, a load by stress generated when a Cu wire is joined easily becomes large in a miniaturized structure in which the source trenches 18 are arranged at the pitch P₂ equal to or less than 1 μm, and yet such a problem can be solved if the semiconductor device 1 according to the present preferred embodiment is used.

Additionally, with respect to the thickness of each of both the third conductive layer 193 and the first barrier layer 194 that are conductive layers harder than Cu (copper), the third conductive layer 193 that is an upper layer and that is relatively close to the joint surface 84 of the first wire 8 is formed thinner than the first barrier layer 194 that is a lower layer and that is more distant from the joint surface 84 than the third conductive layer 193. This makes it possible to easily break the third conductive layer 193 by means of a shock caused when the first wire 8 is joined. As a result, it is possible to disperse stress generated when the first wire 8 is joined throughout the entirety of the first conductive layer 191, hence making it possible to provide a semiconductor device having higher reliability.

Additionally, in the semiconductor device 1, the conductive layer on the semiconductor chip 12 has a layered structure in which the first barrier layer 194 (Ti/TiN), the first conductive layer 191 (AlCu), the third conductive layer 193 (Ti/TiN), and the second conductive layer 192 (AlCu) are laminated in this order. In other words, layers of two kinds of conductive materials are alternately laminated on the semiconductor chip 12. This makes it possible to mutually cancel stress in these conductive layers, hence making it possible to lessen stress (for example, film stress) applied to the semiconductor chip 12. This makes it possible to relax a warp of the semiconductor chip 12, hence making it possible to provide a semiconductor device 1 having high reliability.

Likewise, the sixth conductive layer 197 is formed between the fourth conductive layer 195 and the fifth conductive layer 196 below the second conductive region 52. This enables the sixth conductive layer 197 to lessen a force applied when the second wire 10 (Cu wire) is joined to the fifth conductive layer 196.

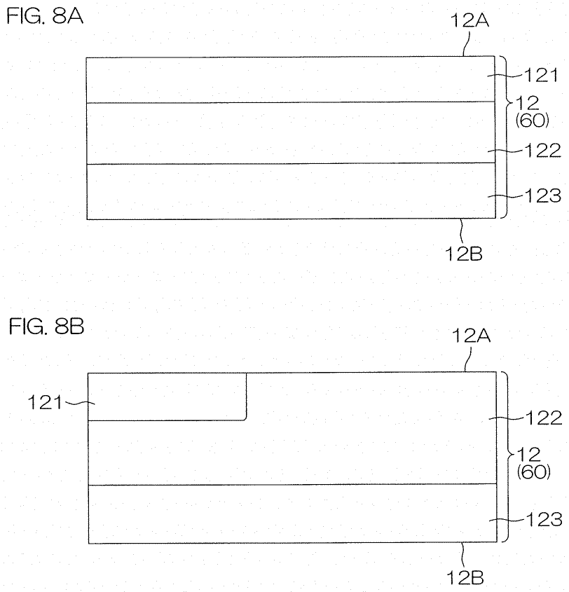

Next, a method of manufacturing the semiconductor device 1 will be described with reference to FIGS. 8A and 8B to FIGS. 18A and 18B. FIGS. 8A and 8B to FIGS. 18A and 18B are longitudinal sectional views showing a part of the manufacturing process of the semiconductor device 1 in order of process steps. Each of FIGS. 8A to 18A is a longitudinal sectional view of a part corresponding to line IV-IV of FIG. 2. Each of FIGS. 8B to 18B is a longitudinal sectional view of a part corresponding to line V-V of FIG. 3.

Referring to FIG. 8A and FIG. 8B, a semiconductor wafer (not shown) is first prepared in order to manufacture the semiconductor device 1. Next, a p type epitaxial layer 60 is formed on the semiconductor wafer. A first principal surface of the epitaxial layer and a second principal surface on the side opposite thereto may correspond to the first principal surface 12A and the second principal surface 12B, respectively. Next, a p type impurity and an n type impurity are selectively injected into a surface layer portion of the first principal surface 12A of the epitaxial layer 60, and a p type first impurity region 121 and an n type second impurity region 122 are formed. Additionally, a p type third impurity region 123 is formed in the remaining region of the epitaxial layer 60. Hence, the semiconductor chip 12 including the epitaxial layer 60 is formed.

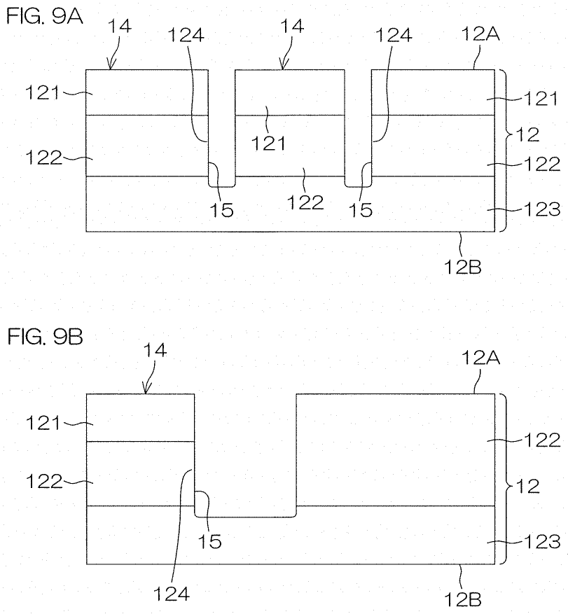

Next, referring to FIG. 9A and FIG. 9B, the gate trench 15 is formed. For example, a photoresist (not shown) is formed on the first principal surface 12A of the semiconductor chip 12, and the gate trench 15 is selectively formed by etching through the photoresist.

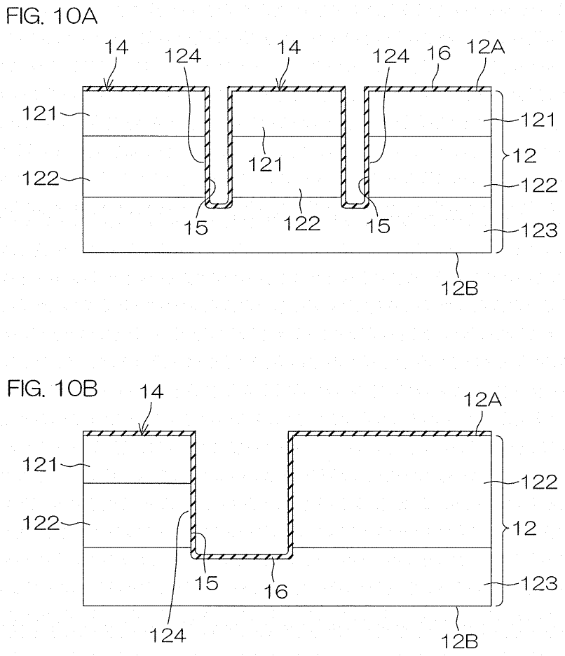

Next, referring to FIG. 10A and FIG. 10B, the first principal surface 12A of the semiconductor chip 12 and the inner surface of the gate trench 15 are oxidized by heat treatment according to, for example, a thermal oxidation method or the like. Hence, the gate insulating film 16 is formed on the first principal surface 12A and the inner surface of the gate trench 15.

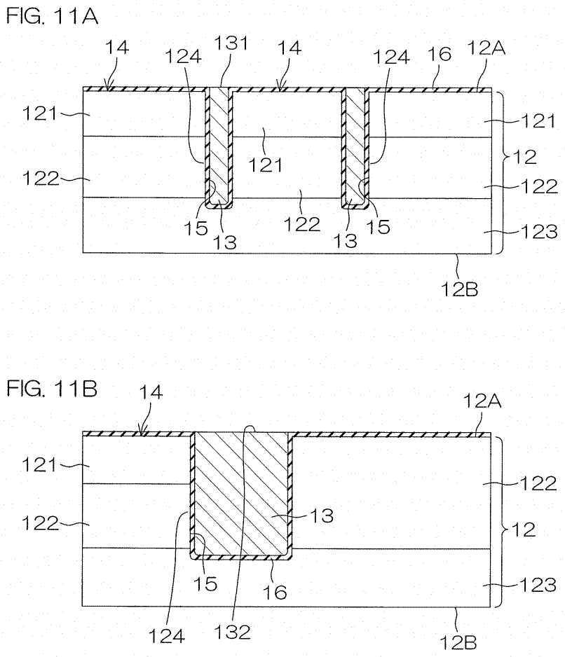

Next, referring to FIG. 11A and FIG. 11B, the gate electrode 13 is formed. A polysilicon film is formed on the gate insulating film 16 by, for example, a CVD method. Thereafter, unnecessary portions of the polysilicon film are removed by etching or the like, and, as a result, the gate electrode 13 is formed.

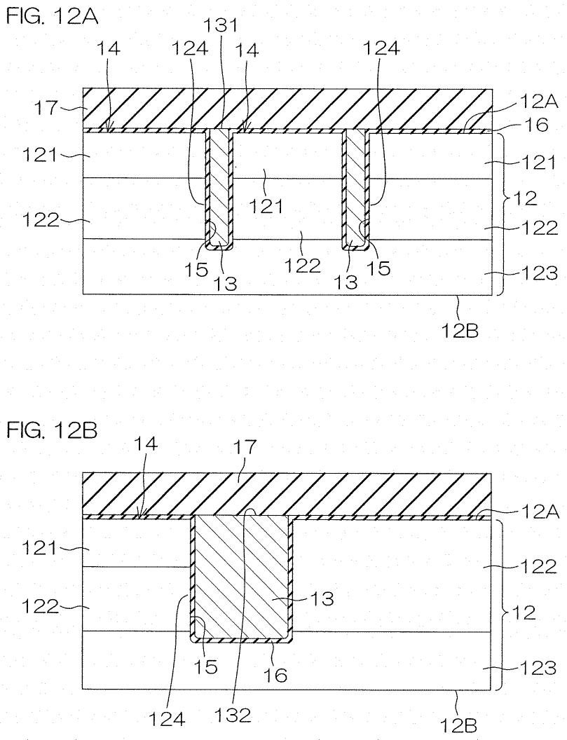

Next, referring to FIG. 12A and FIG. 12B, the interlayer insulating film 17 is formed on the first principal surface 12A so as to cover the gate insulating film 16 and the gate electrode 13 by, for example, the CVD method.

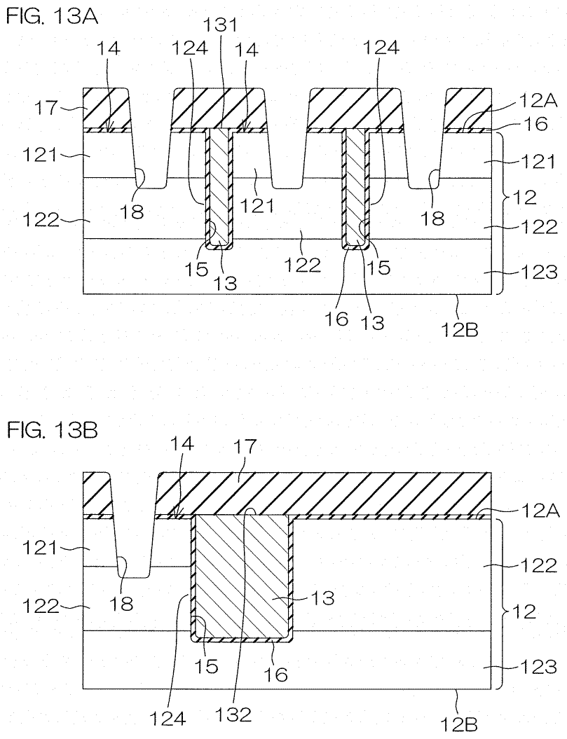

Next, referring to FIG. 13A and FIG. 13B, the interlayer insulating film 17, the gate insulating film 16, the first impurity region 121, and the second impurity region 122 are partially etched, and, as a result, the source trench 18 is formed.

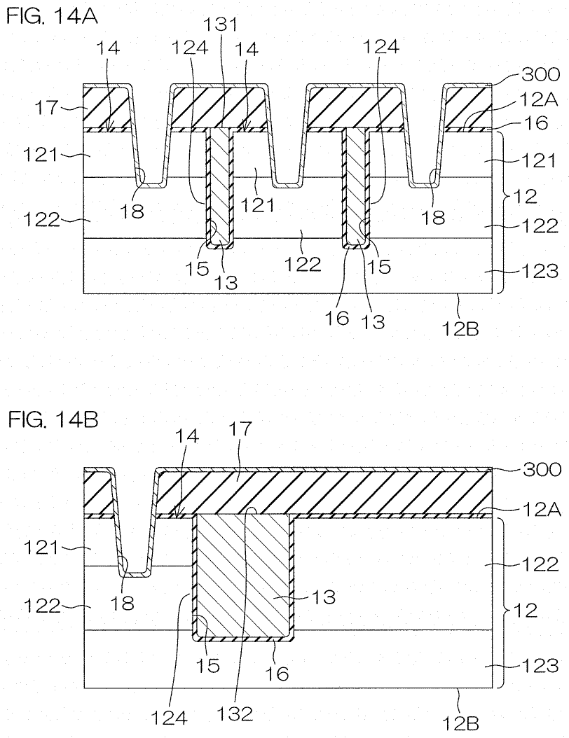

Next, referring to FIG. 14A and FIG. 14B, a first barrier material layer 300 is formed. The first barrier material layer 300 is formed by depositing an electrode material according to, for example, a sputtering method or the like. The first barrier material layer 300 includes, for example, a material including Ti. As the first barrier material layer 300, a Ti film may be first formed by the sputtering method, and a TiN film may be formed on the Ti film by the sputtering method, and, as a result, a layered structure consisting of the Ti film and the TiN film may be formed. The first barrier material layer 300 is formed continuously between the inner surface of the source trench 18 and the upper surface of the interlayer insulating film 17 so as to be contiguous to these surfaces.

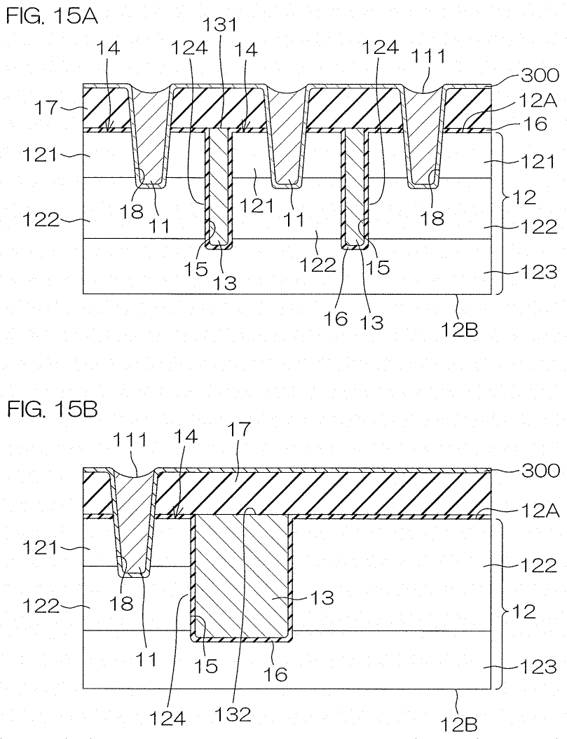

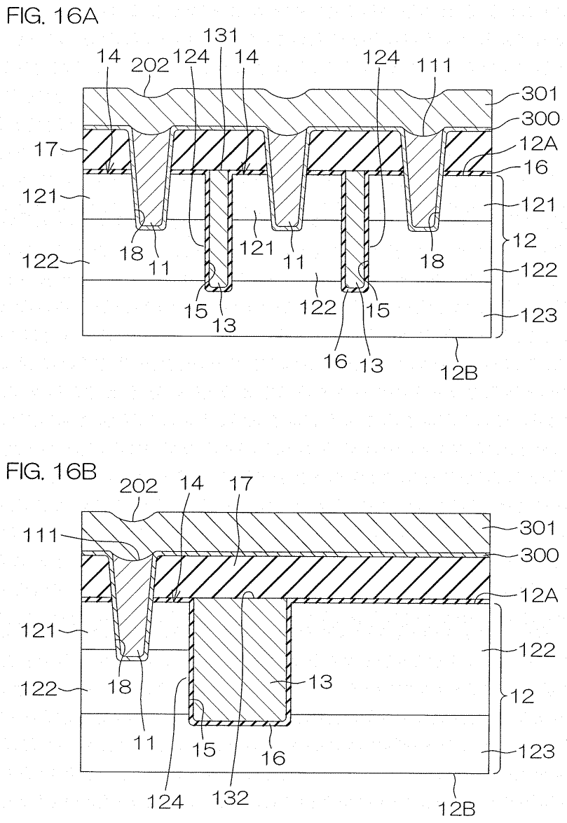

Next, referring to FIG. 15A and FIG. 15B, the contact plug 11 is formed in the source trench 18. An electrode material is deposited on the first barrier material layer 300 according to, for example, the CVD method or the like. Thereafter, unnecessary portions of this electrode material are removed by etching or the like, and, as a result, the electrode material that remains on the source trench 18 is formed as the contact plug 11. The contact plug 11 includes, for example, a material including W.

Next, referring to FIG. 16A and FIG. 16B, a first conductive material layer 301 is formed. An electrode material is deposited on the first barrier material layer 300 and on the contact plug 11 according to, for example, the sputtering method or the like, and, as a result, the first conductive material layer 301 is formed. The first conductive material layer 301 may include, for example, AlCu.

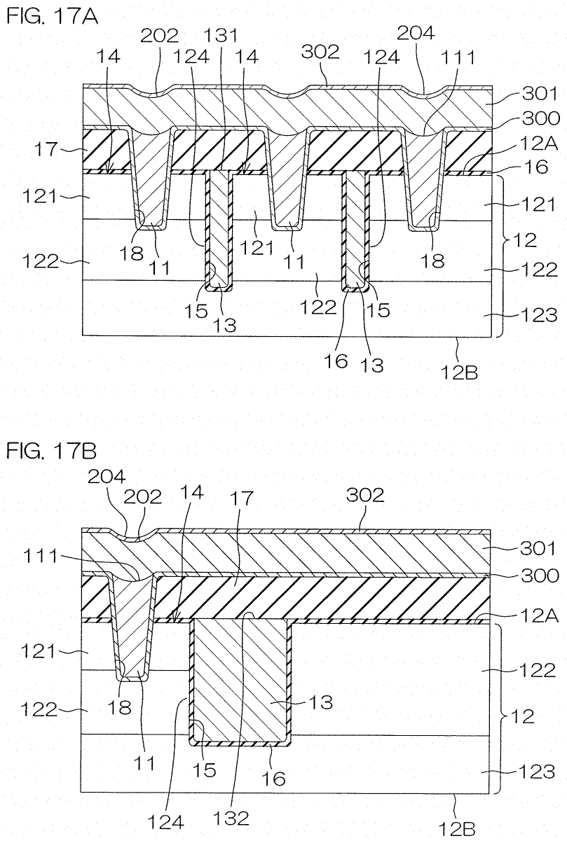

Next, referring to FIG. 17A and FIG. 17B, a second barrier material layer 302 is formed. The second barrier material layer 302 includes, for example, a material including Ti. As the second barrier material layer 302, a Ti film may be first formed by the sputtering method, and a TiN film may be formed on the Ti film by the sputtering method, and, as a result, a layered structure consisting of the Ti film and the TiN film may be formed. If the same material as the first barrier material layer 300 is used as the second barrier material layer 302, the material can be used in a shared manner, thus making it possible to improve the productivity of the semiconductor device 1.

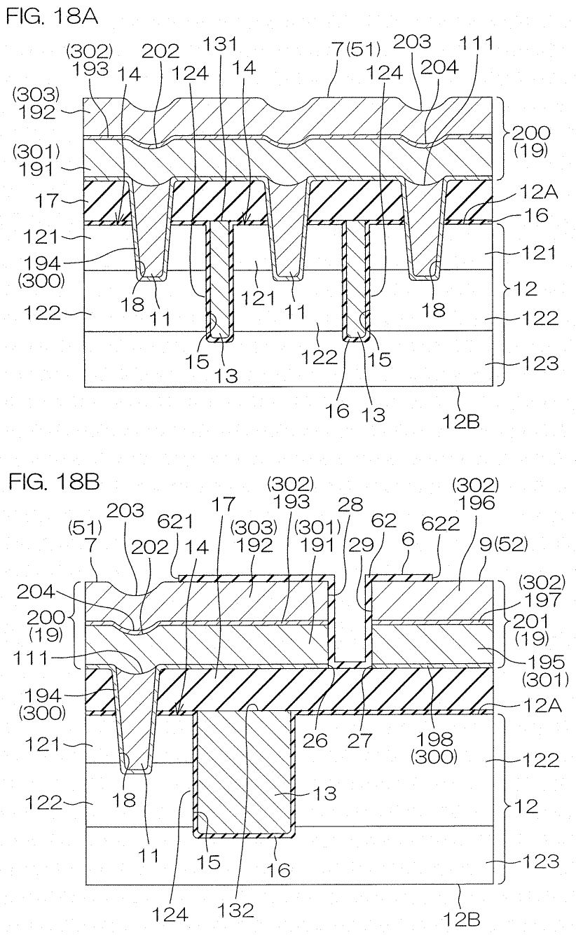

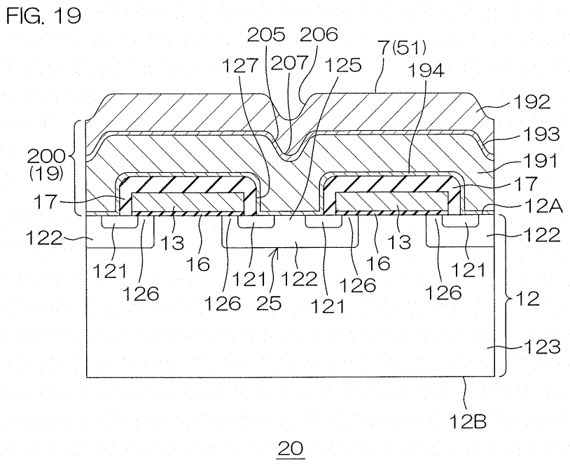

Next, referring to FIG. 18A and FIG. 18B, a second conductive material layer 303 is formed. The second conductive material layer 303 is formed by depositing an electrode material on the second barrier material layer 302 according to, for example, the sputtering method or the like. The second conductive material layer 303 may include, for example, AlCu. If the same material as the first conductive material layer 301 is used as the second conductive material layer 303, the material can be used in a shared manner, thus making it possible to improve the productivity of the semiconductor device 1.

Next, referring to FIG. 18B, the second conductive material layer 303, the second barrier material layer 302, the first conductive material layer 301, and the first barrier material layer 300 are selectively etched, and, as a result, these layers 300 to 303 are separated into a plurality of regions. Hence, the first conductive portion 200 and the second conductive portion 201 of the conductive layer 19 are formed. Thereafter, an insulating material is deposited so as to cover the conductive layer 19, and this insulating material is selectively etched, and, as a result, the insulating film 62 having the first opening 621 and the second opening 622 is formed.

Next, a drain electrode layer (not shown) is formed on a back surface of the semiconductor wafer by a vapor deposition method, the sputtering method, a plating method, or the like, and then a plurality of semiconductor devices 1 is cut out from the semiconductor wafer. The semiconductor device 1 is manufactured through the process including the aforementioned steps.

### Second Preferred Embodiment

Next, a cross-sectional structure of a semiconductor device 20 according to a second preferred embodiment of the present disclosure will be described with reference to FIG. 19. FIG. 19 is a schematic cross-sectional view of the semiconductor device 20 according to the second preferred embodiment of the present disclosure.

The semiconductor device 1 of the first preferred embodiment mentioned above has a MISFET having a trench gate structure as the device structure, whereas the semiconductor device 20 has a MISFET having a planar gate structure.

The second impurity region 122 is selectively formed at the surface layer portion of the first principal surface 12A of the semiconductor chip 12 below the first conductive region 51 in the semiconductor device 20. The second impurity regions 122 are formed at a distance from each other. The first impurity region 121 is formed at the surface layer portion of the second impurity region 122 at a distance from a peripheral edge of the second impurity region 122 toward the inside of the second impurity region 122. The first impurity region 121 is formed in, for example, an annular shape. A part of the second impurity region 122 is exposed as a contact portion 125 from the first principal surface 12A through a central portion of the first impurity region 121. Additionally, a region between a peripheral edge of the first impurity region 121 and the peripheral edge of the second impurity region 122 is a channel region 126 in the second impurity region 122.

As thus described, a transistor cell 25 of the semiconductor device 20 is defined by each of the second impurity regions 122 and by the first impurity region 121 within this second impurity region 122. The arrangement pattern of the transistor cells 25 may be formed in a staggered manner, a matrix manner, a stripe manner, etc., in the same way as in the first preferred embodiment.

The third impurity region 123 is formed at the surface layer portion of the second principal surface 12B of the semiconductor chip 12 so as to be contiguous to the second impurity region 122. Additionally, a part of the third impurity region 123 is exposed from the first principal surface 12A through a space between the adjoining second impurity regions 122.

The gate insulating film 16 is formed on the first principal surface 12A of the semiconductor chip 12 so as to cover the channel region 126. The gate insulating film 16 straddles the adjoining second impurity regions 122. The gate electrode 13 is formed on the gate insulating film 16, and faces the channel region 126 with the gate insulating film 16 between the gate electrode 13 and the channel region 126.

The interlayer insulating film 17 is formed on the first principal surface 12A of the semiconductor chip 12 so as to cover the gate electrode 13. The interlayer insulating film 17 has a contact hole 127 formed to expose the first impurity region 121 and the second impurity region 122 (contact portion 125).

The first barrier layer 194 has its one surface and its one other surface that are formed so as to follow an inner surface of the contact hole 127 and the upper surface of the interlayer insulating film 17, and makes a direct electric current passage between the first barrier layer 194 and the first and second impurity regions 121, 122.

The first conductive layer 191 is formed on the first barrier layer 194. The first conductive layer 191 makes an electric current passage between the first conductive layer 191 and the first and second impurity regions 121, 122 through the first barrier layer 194.

The second conductive layer 192 is formed on the first conductive layer 191 with the third conductive layer 193 between the second conductive layer 192 and the first conductive layer 191. The second conductive layer 192 is a surface conductive layer that is an outermost surface of the first conductive portion 200, and is a layer to which the first wire 8 mentioned above is connected. Therefore, an upper surface of the second conductive layer 192 is exposed as the first pad 7. The second conductive layer 192 makes an electric current passage between the second conductive layer 192 and the first and second impurity regions 121, 122 through the first barrier layer 194, through the third conductive layer 193, and through the first conductive layer 191.

The third conductive layer 193 is formed between the first conductive layer 191 and the second conductive layer 192, and is sandwiched between the first conductive layer 191 and the second conductive layer 192.

The contact hole 127 is formed in the interlayer insulating film 17 as described above. Therefore, a concave portion 205 may be formed at a position, which faces the contact hole 127 in the layered direction of the first conductive portion 200, of the upper surface of the first conductive layer 191. Additionally, a concave portion 206 may be formed at a position, which faces the contact hole 127 in the layered direction of the first conductive portion 200, of the upper surface of the second conductive layer 192. Additionally, a concave portion 207 may be formed at a position, which faces the upper surface 111 in the layered direction of the first conductive portion 200, of the upper surface of the third conductive layer 193.

As described above, likewise, the third conductive layer 193 is formed between the first conductive layer 191 and the second conductive layer 192 below the first conductive region 51 in the semiconductor device 20. Hence, a force applied when the first wire 8 (Cu wire) is joined to the second conductive layer 192 is lessened by the third conductive layer 193. This makes it possible to lessen the load of stress to the device structure including the transistor cell 25, hence making it possible to provide a semiconductor device 20 having high reliability.

Additionally, if the concave portions 205 to 207 are formed in the first conductive portion 200, there is a concern that a load by stress generated when the Cu wire is joined will become larger than when these concave portions are not formed, and cracks will be made in, for example, the interlayer insulating film 17, etc., directly under the conductive layer 19. The semiconductor device 20 according to the present preferred embodiment is also effective for a structure in which a load by such stress easily becomes large, and, as a result, it is possible to provide a semiconductor device 20 having high reliability.

Additionally, in the semiconductor device 20, the conductive layer on the semiconductor chip 12 has a layered structure in which the first barrier layer 194 (Ti/TiN), the first conductive layer 191 (AlCu), the third conductive layer 193 (Ti/TiN), and the second conductive layer 192 (AlCu) are laminated in this order. In other words, layers of two kinds of conductive materials are alternately laminated on the semiconductor chip 12. This makes it possible to mutually cancel stress in these conductive layers, hence making it possible to lessen stress (for example, film stress) applied to the semiconductor chip 12. This makes it possible to relax a warp of the semiconductor chip 12, hence making it possible to provide a semiconductor device 20 having high reliability.

The preferred embodiments of the present disclosure have been described as above, and yet the present disclosure can be embodied in other modes.

For example, an arrangement in which the conductivity type of each of the semiconductor parts of the semiconductor devices 1 and 20 has been inverted may be employed. For example, the p type part may be an n type, and the n type part may be a p type in the semiconductor devices 1 and 20.

Additionally, the MISFET has been employed as an example of the device structure of each of the semiconductor devices 1 and 20 in the aforementioned preferred embodiments, and yet the device structure of each of the semiconductor devices 1 and 20 may be, for example, IGBT (Insulated Gate Bipolar Transistor), a pn diode, a schottky barrier diode, or the like.

Besides, various design changes can be made within the scope of the matter recited in the appended claims.

This application corresponds to Japanese Patent Application No. 2020-126710 filed in the Japan Patent Office on Jul. 27, 2020, the entire disclosure of which is incorporated herein by reference.

### REFERENCE SIGNS LIST

1 semiconductor device
3: semiconductor element
8: first wire
10: second wire
11: contact plug
12: semiconductor chip
12A: first principal surface
12B: second principal surface
13: gate electrode
14: transistor cell
15: gate trench
16: gate insulating film
17: interlayer insulating film
18: source trench
19: conductive layer
20: semiconductor device
25: transistor cell
51: first conductive region
52: second conductive region
83: joint portion
84: joint surface
85: boundary
86: joint portion
87: raised portion
88: joint portion
89: boundary
90: joint surface
91: joint portion
92: raised portion
111: upper surface
121: first impurity region
122: second impurity region
123: third impurity region
124: channel region
126: channel region
191: first conductive layer
192: second conductive layer
193: third conductive layer
194: first barrier layer
195: fourth conductive layer
196: fifth conductive layer
197: sixth conductive layer
198: second barrier layer
200: first conductive portion
201: second conductive portion
202: concave portion
203: concave portion
204: concave portion
205: concave portion
206: concave portion
207: concave portion
P₁: pitch
P₂: pitch
T₁: thickness
T₂: thickness
T₃: thickness
T₄: thickness
φ₁: diameter
φ₂: diameter
φ₃: diameter
φ₄: diameter

1. A semiconductor device comprising:
a semiconductor chip having a device forming surface on which a device structure is formed;
a first conductive layer formed on the device forming surface of the semiconductor chip;
a second conductive layer formed on the first conductive layer;
a first wire that is connected to the second conductive layer and that is made of a material composed mainly of copper; and
a third conductive layer that is formed between the first conductive layer and the second conductive layer and that includes a material harder than copper.

2. The semiconductor device according to claim 1, further comprising a fourth conductive layer that is formed between the semiconductor chip and the first conductive layer and that includes a material harder than copper.

3. The semiconductor device according to claim 2, wherein the fourth conductive layer includes a same material as the third conductive layer.

4. The semiconductor device according to claim 2, wherein a thickness of the third conductive layer is equal to or less than a thickness of the fourth conductive layer.

5. The semiconductor device according to claim 1, wherein the device structure includes a concave portion formed at the semiconductor chip and an electroconductive embedded body embedded in the concave portion, and
the first conductive layer covers the concave portion.

6. The semiconductor device according to claim 5, wherein the device structure includes a first conductivity type first region and a second conductivity type second region contiguous to the first region, each of the first region and the second region being exposed to the concave portion, and
the embedded body is electrically connected to the first region and to the second region.

7. The semiconductor device according to claim 1, further comprising:
an insulating layer formed between the semiconductor chip and the first conductive layer;
a concave portion that passes through the insulating layer and that reaches an intermediate position of the semiconductor chip in a thickness direction of the semiconductor chip;
a fourth conductive layer that is conformal to an inner surface of the concave portion and an upper surface of the insulating layer and that includes a material harder than copper; and
an electroconductive embedded body embedded in the concave portion with the fourth conductive layer between the embedded body and the concave portion.

8. The semiconductor device according to claim 5, wherein the concave portions are arranged at a pitch of 1 μm or less.

9. The semiconductor device according to claim 1, comprising:
a fifth conductive layer that is formed on the device forming surface of the semiconductor chip and that is separated from the first conductive layer;
a sixth conductive layer formed on the fifth conductive layer;
a second wire connected to the sixth conductive layer; and
a seventh conductive layer that is formed between the fifth conductive layer and the sixth conductive layer and that includes a material harder than copper.

10. The semiconductor device according to claim 9, wherein a diameter of the second wire is equal to a diameter of the first wire.

11. The semiconductor device according to claim 9, wherein the second wire includes a wire made of a material composed mainly of copper.

12. The semiconductor device according to claim 9, wherein the device structure includes:
a gate electrode and
a first impurity region and a second impurity region that are formed at the semiconductor chip and that make an electric current passage between the first impurity region and the second impurity region through a channel formed by applying a voltage to the gate electrode; and wherein
the first wire is electrically connected to the first impurity region via the second conductive layer and the first conductive layer, and
the second wire is electrically connected to the gate electrode via the sixth conductive layer and the fifth conductive layer.

13. The semiconductor device according to claim 1, wherein the third conductive layer includes at least one of Ti and W.

14. The semiconductor device according to claim 1, wherein a thickness of the third conductive layer is equal to or less than 700 Å.

15. The semiconductor device according to claim 1, wherein the first conductive layer and the second conductive layer are made of a same material.

16. The semiconductor device according to claim 15, wherein the first conductive layer and the second conductive layer include AlCu.

17. The semiconductor device according to claim 1, wherein a thickness of the second conductive layer is not less than 2 μm and not more than 4.5 μm.

18. The semiconductor device according to claim 1, wherein the second conductive layer has a first thickness in a joint portion between the second conductive layer and the first wire, and has a second thickness larger than the first thickness around the joint portion.
